(19) United States
(12) Patent Application Publication
(10) Pub. No.: US 2006/0115936 A1
(43) Pub. Date: Jun. 1, 2006

(54) Method of manufacturing semiconductor device with reduced junction leakage current and gate electrode resistance of transistor

(75) Inventors: Kiyonori Oyu, Tokyo (JP); Keizo Kawakita, Tokyo (JP); Kensuke Okonogi, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY, INC., TOKYO (JP)

(21) Appl. No.: 11/288,123

(22) Filed: Nov. 29, 2005

(30) Foreign Application Priority Data
Nov. 30, 2004 (JP) 2004-346016

(51) Int. Cl. H01L 21/84

(52) U.S. Cl. 438/151

(57) ABSTRACT

After a gate electrode made of a material containing a refractory metal is formed, the gate electrode is oxidized to form an oxide film for covering an exposed side surface of the gate electrode, at a predetermined temperature in an initial oxidization phase, and thereafter, the gate electrode is oxidized at a temperature higher than the predetermined temperature in an additional oxidization phase. Since the side surface of the gate electrode is covered with the oxide film in the initial oxidization phase, the refractory metal is prevented from being scattered from the side surface of the gate electrode in the additional oxidization phase. The layer resistance of the film containing the refractory metal is reduced because the additional oxidization phase is performed at the higher temperature.

### BACKGROUND OF THE INVENTION

1. Field of the Invention

The present invention relates to a method of manufacturing a semiconductor device having a gate electrode used in a transistor.

2. Description of the Related Art

A memory cell of a DRAM (Dynamic Random Access Memory) (hereinafter referred to as “DRAM cell”) as a typical example of conventional semiconductor device will briefly be described below. A conventional DRAM is disclosed in FIG. 19 of Japanese laid-open patent publication No. 2003-17586 (hereinafter referred to as “Patent Document 1”).

FIG. 1 of the accompanying drawings is a schematic cross-sectional view of a conventional DRAM cell. As shown in FIG. 1, the conventional DRAM cell has a capacitor 10 for storing an electric charge and a cell transistor for supplying an electric charger to the capacitor 10 checking whether an electric charge is stored in the capacitor 10 or not. Structural details of the cell transistor will be described below.

An n-type buried well layer (not shown) is disposed in a silicon substrate, and p-type well layer 3 to which a substrate potential is applied is disposed in the surface of the n-type buried well layer which faces the silicon substrate. The cell transistor has an active region disposed in the surface of p-type well layer 3 which faces the silicon substrate. The active region is surrounded by a groove-like device isolating region in which insulating layer 2 is buried, and p-type channel doped layer 4 for setting a threshold voltage is disposed in the surface of the active region.

Gate electrodes 6 are disposed over the active region with gate oxide film 7, which serves as a gate insulating film, interposed there between. Regions of the active area over which gate electrodes 6 are not disposed include n-type low-concentration diffused layers 9 which will serve as source and drain electrodes. One of n-type low-concentration diffused layers 9 is connected to a lower electrode of a capacitor 10 through plug 5 and plug 11. Another n-type low-concentration diffused layer is connected to bit line 1 through plug 5. Gate electrodes 6 serve as word lines. As shown in FIG. 1, an adjacent cell transistor shares bit line 1.

Each of gate electrodes 6 is of a laminated structure including phosphorus-doped polycrystalline silicon film 66 and tungsten silicide film 63. Protective film 27 is disposed on gate electrodes 6. Side spacers 8 are disposed on opposite side walls of each of gate electrodes 6 for insulating plugs 5 and gate electrodes 6 from each other. Silicon oxide films 44 are interposed between gate electrodes 6 and side spacers 8 for increasing the withstand voltages of the gate oxide films.

Interlayer insulating film 12 is disposed on protective film 27, and interlayer insulating films 13, 14 are successively disposed on interlayer insulating film 12. Plugs 5 are placed in respective openings extending from interlayer insulating film 12 to the surfaces of n-type low-concentration diffused layers 9. Bit line 1 is connected to plug 5 through an opening defined in interlayer insulating film 13. Plugs 11 are placed in respective openings defined in interlayer insulating films 13, 14.

In the structure shown in FIG. 1, phosphorus-doped layers 91, which serve as impurity-diffused layers for electric field relaxation, as disclosed in Japanese patent No. 3212150, are disposed deeper than n-type low-concentration diffused layers 9 in the silicon substrate. Phosphorus-doped layers 91 are produced by introducing phosphorus ions into the silicon substrate and then heating the assembly after the openings to be filled by plugs 5 have been formed.

A fabrication process from the formation of the n-type buried well layer to the formation of n-type low-concentration diffused layers 9 of the cell transistor for manufacturing the DRAM cell shown in FIG. 1 will briefly be described below based on Patent Document 1. The device separating process and the process subsequent to the formation of side spacers 8 will not be described in detail below as they are identical to those described in Patent Document 1.

A silicon oxide film is formed on the surface of a silicon substrate, and as shown in FIG. 1, a groove-like device isolating region in which insulating layer 2 is buried is formed according to the process described in Patent Document 1. Then, phosphorus ions are implanted at 1000 keV with 1E13/cm² to form an buried well layer. Then, ions of a p-type impurity of boron are implanted to form p-type well layer 3 according to four conditions, i.e., at 300 keV with 1E13/cm², at 150 keV with 5E12/cm², at 50 keV with 1E12/cm², and at 10 keV with 2E12/cm². Thereafter, though not disclosed in Patent Document 1, the assembly is heated to 1000° C. for activating the boron.

Then, boron ions are implanted at 10 keV with 7E12/cm² to form p-type channel doped layer 4. After the silicon oxide film on the surface of the silicon substrate is removed, gate oxide film 7 is formed by thermal oxidation. The heat treatment for forming gate oxide film 7 also activate the boron of p-type channel doped layer 4. Then, phosphorus-doped polycrystalline silicon film 66 is deposited to about 100 nm, and then tungsten silicide film 63 is deposited to about 150 nm on phosphorus-doped polycrystalline silicon film 66, thereby forming the material of gate electrodes 6 as a two-layer film. Thereafter, a silicon oxide film and a silicon nitride film are deposited as protective film 27 for gate electrode processing on tungsten suicide film 63. However, protective film 27 may comprise an insulating film other than a silicon oxide film and a silicon nitride film.

After a resist having a predetermined pattern is formed by lithography, the assembly is subjected to anisotropic dry etching from above the resist, thereby removing protective film 27, tungsten silicide film 63, and phosphorus-doped polycrystalline silicon film 66 in areas not covered with the resist, thereby forming gate electrodes 6. At this time, the surface of gate oxide film 7 is exposed. The anisotropic dry etching is performed under conditions to leave gate oxide film 7 unremoved.

After the resist is removed, the sides of gate electrodes 6 are oxidized by thermal oxidation to form silicon oxide films 44 thereon. At this time, the areas of gate oxide film which were exposed to the anisotropic dry etching for forming gate electrodes 6 have their thickness increased. For forming silicon oxide films 44, the sides of gate electrodes 6 are oxidized by thermal oxidation at 1050° C. for several tens of seconds in a dry oxygen atmosphere in order for a bare silicon substrate for measuring the thickness of a grown film to have an oxide film thickness in the range from 4 to 7 nm. Thereafter, phosphorus ions are implanted at 10 keV with 2E13/cm² to form n-type low-concentration diffused layers 9 which will serve as source and drain electrodes. The assembly is then heated for activating the implanted phosphorus. The heat treatment for activating the implanted phosphorus may be performed on n-type low-concentration diffused layers 9 of the cell transistor, or may be performed at the time low-concentration diffused layers in peripheral transistors disposed around the memory cell block are activated. At any rate, the heat treatment is performed at 900 to 1000° C. for several tens of seconds in a nitrogen atmosphere.

The conventional semiconductor device described above suffers at least two problems to be described below.

The first problem is that since the sides of gate electrodes 6 are oxidized at 1050° C. for forming silicon oxide films 44 thereon, the processed surfaces of tungsten silicide film 63, which serves as a material of gate electrodes 6, tend to cause an increased tungsten contamination, which increases a junction leakage current. In DRAMs, an increased junction leakage current shortens an data retention time. Reasons for such an increased tungsten contamination will be described below.

FIGS. 2A through 2D of the accompanying drawings are fragmentary cross-sectional views of a gate electrode, which are illustrative of the above conventional problem.

As shown in FIG. 2A, when gate electrode 6 is etched, an area where gate oxide film 7 is exposed suffers damage 62 due to dry etching. The damaged area is more liable to absorb tungsten molecules discharged from a processed surface of tungsten silicide film 63, causing a tungsten contamination in gate oxide film 7. When the assembly is thermally oxidized at 1050° C., as shown in FIG. 2B, since the oxidizing temperature is relatively high, more tungsten molecules 64 are absorbed by gate oxide film 7 which is suffering damage 62 in an initial stage of the thermal oxidization, resulting in a greater tungsten contamination. Tungsten molecules 64 that are diffused from gate oxide film 7 into the silicon substrate when gate oxide film 7 is additionally thermally oxidized form trap level responsible for a junction leakage current.

As shown in FIG. 2C, phosphorus ions 65 are implanted to form n-type low-concentration diffused layers 9 after the thermal oxidization. When the implanted phosphorus ions 65 with a certain kinetic energy impinge upon tungsten molecules 64 that remain in gate oxide film 7, tungsten molecules 64 are knocked on into the silicon substrate, as shown in FIG. 2D, thereby forming trap level responsible for a junction leakage current as is the case with the tungsten contamination shown in FIG. 2B.

The second problem is that at the above temperature for oxidizing the sides of gate electrode 6, the grain growth of tungsten silicide film 63 is so insufficient that the layer resistance thereof is not sufficiently lowered. If the layer resistance of tungsten silicide film 63 is high, then gate electrode 6 has a high resistance itself. If gate electrode 6 of high resistance is used as a word line in a DRAM, then the operation of the DRAM is slow because of an interconnection delay. Though various heat treatments are performed after the side oxidization, they are unable to sufficiently lower the layer resistance of tungsten silicide film 63 because the temperatures of those various heat treatments are lower than the side oxidization temperature.

The relationship between the heat treatment temperature and the layer resistance of the tungsten silicide film will be described below. FIG. 3 of the accompanying drawings is a graph showing the relationship between the heat treatment temperature and the layer resistance. In FIG. 3, the horizontal axis represents the heat treatment temperature and the vertical axis the normalized layer resistance which has a value of 1 achieved when the heat treatment temperature is 1100° C. It can be seen from FIG. 3 that the layer resistance is lower as the side oxidization temperature is higher.

The relationship between the heat treatment temperature and the scattered amount of tungsten (W). FIG. 4 shows the relationship between the heat treatment temperature and the scattered amount of W. In FIG. 4, the horizontal axis represents the heat treatment temperature and the vertical axis the normalized scattered amount of W which has a value of 1 achieved when the heat treatment temperature is 1100° C. As can be seen from FIG. 4, the scattered amount of tungsten increases exponentially as the heat treatment temperature increases. Therefore, a tungsten contamination also increases exponentially as the heat treatment temperature increases, posing a limitation on efforts to increase the side oxidization temperature discussed above with respect to the first problem. If the heat treatment temperature increases from 1050° C. to 1100° C., then the tungsten contamination increases three or four times, resulting in a greater leakage current. Though the layer resistance can be reduced by increasing the temperature of the heat treatment to be performed after the transistor is fabricated, there is a limitation on efforts to increase the temperature of the heat treatment as the threshold voltage of a MOS (Metal Oxide Semiconductor) transistor varies due to the diffusion of an impurity in diffused layers of source and drain electrodes.

As described above, there is a trade-off between the tungsten contamination and the layer resistance of the tungsten silicide film upon the side oxidization of gate electrodes 6. As a consequence, the oxidization temperature cannot easily be changed.

### SUMMARY OF THE INVENTION

It is an object of the present invention to provide a method of manufacturing a semiconductor device to prevent a junction leakage current from increasing and also to reduce the layer resistance of a gate electrode.

According to the present invention, a method of manufacturing a semiconductor device comprises the steps of forming a gate electrode made of a material containing a refractory metal, then oxidizing the gate electrode to form an oxide film for covering an exposed side surface of the gate electrode, at a predetermined temperature in an initial oxidization phase, and thereafter, oxidizing the gate electrode at a temperature higher than the predetermined temperature in an additional oxidization phase.

Since the side surface of the gate electrode is covered with the oxide film in the initial oxidization phase, the refractory metal is prevented from being scattered from the side surface of the gate electrode in the additional oxidization phase. The layer resistance of the film containing the refractory metal is reduced because the additional oxidization phase is performed at the higher temperature. Therefore, upon side oxidization after the gate electrode of a MOS transistor or the like is processed, a refractory metal contamination from the gate electrode is reduced to prevent a junction leakage current from increasing, and the layer resistance of the film containing the refractory metal is reduced to increase the operating speed of the transistor.

The above and other objects, features, and advantages of the present invention will become apparent from the following description with reference to the accompanying drawings which illustrate examples of the present invention.

### BRIEF DESCRIPTION OF THE DRAWINGS

FIG. 1 is a schematic cross-sectional view of a conventional DRAM cell;

FIGS. 2A through 2D are fragmentary cross-sectional views of a gate electrode, which are illustrative of a conventional problem;

FIG. 3 is a graph showing the relationship between the heat treatment temperature and the layer resistance;

FIG. 4 is a graph showing the relationship between the heat treatment temperature and the tungsten contamination;

FIG. 5 is a diagram showing a temperature sequence as an example of an oxidizing condition according to an example of the present invention;

FIGS. 6A and 6B are fragmentary cross-sectional views of a gate electrode, showing the manner in which the treatment condition shown in FIG. 5 is applied to the side oxidization of the gate electrode;

FIGS. 7A through 7H are cross-sectional views illustrative of a process of manufacturing a DRAM cell based on a method according to the present invention; and

FIG. 8 is a graph showing the data retention characteristics of a DRAM manufactured by the method according to the present invention.

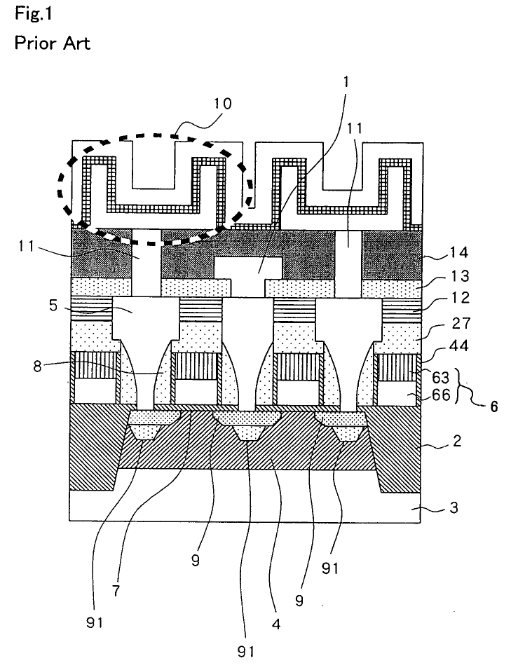

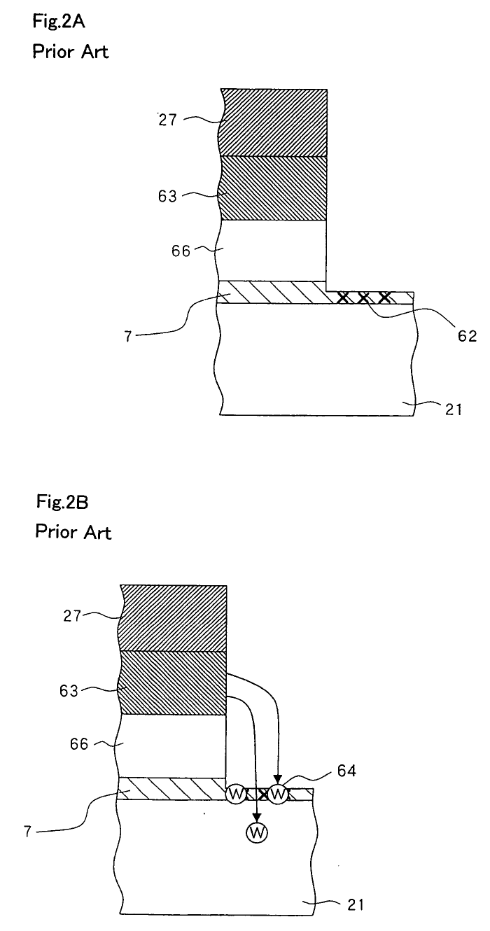

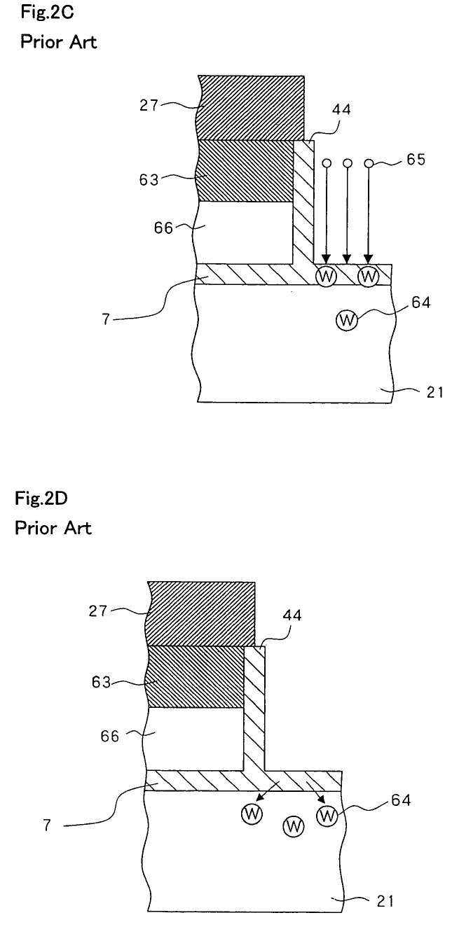

### DETAILED DESCRIPTION OF THE PREFERRED EMBODIMENT

A method of manufacturing a semiconductor device according to the present invention resides in that when an oxide film is formed by thermal oxidization on the side walls of a gate electrode of a transistor used in a semiconductor device, the thermal oxidization is performed at a lower temperature in an initial stage thereof and thereafter performed at a higher temperature. Processing details for forming the oxide film will be described in detail below.

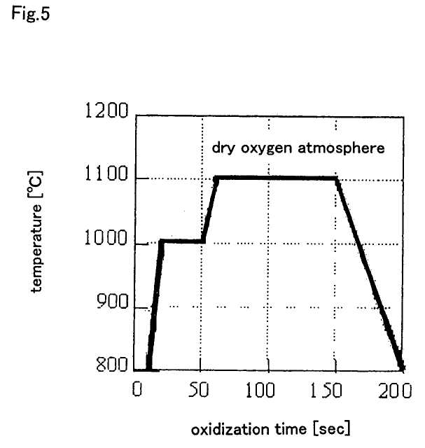

FIG. 5 shows a temperature sequence as an example of an oxidizing condition according to an example of the present invention.

As shown in FIG. 5, after a semiconductor substrate with a gate electrode disposed thereon is heated from the room temperature to 800° C., the temperature of the semiconductor substrate is increased up to 1000° C. at a constant rate. When the temperature reaches 1000° C. which is lower than 1050° C., the assembly is oxidized at 1000° C. in a dry oxygen atmosphere, forming an oxide film having a thickness in the range from 1 to 3 nm. Then, the temperature of the semiconductor substrate is increased up to 1100° C. at a constant rate. When the temperature reaches 1100° C. which is higher than the initial oxidization temperature, the assembly is oxidized at 1100° C. in a dry oxygen atmosphere, forming an oxide film having a desired thickness. Thereafter, the temperature of the semiconductor substrate is lowered to 800° C. at a constant rate, and then lowered to the room temperature by way of natural heat radiation. In the oxidization process shown in FIG. 5, the oxidization process at the lower temperature is referred to as an initial oxidization phase, and the oxidization process at the higher temperature is referred to as an additional oxidization phase.

According to the temperature sequence shown in FIG. 5, the temperature of the initial oxidization phase is 1000° C., and the temperature of the additional oxidization phase is 1100° C. The oxide film having a thickness in the range from 1 to 3 nm may be formed at a temperature of 1000° C. or lower in the initial oxidization phase, and the film having a desired thickness may be formed at a temperature of 1050° C. or higher in the additional oxidization phase.

A process of forming a silicon oxide film on a side wall of a gate electrode of a transistor according to a thermal oxidization process based on the temperature sequence shown in FIG. 5 will be described below.

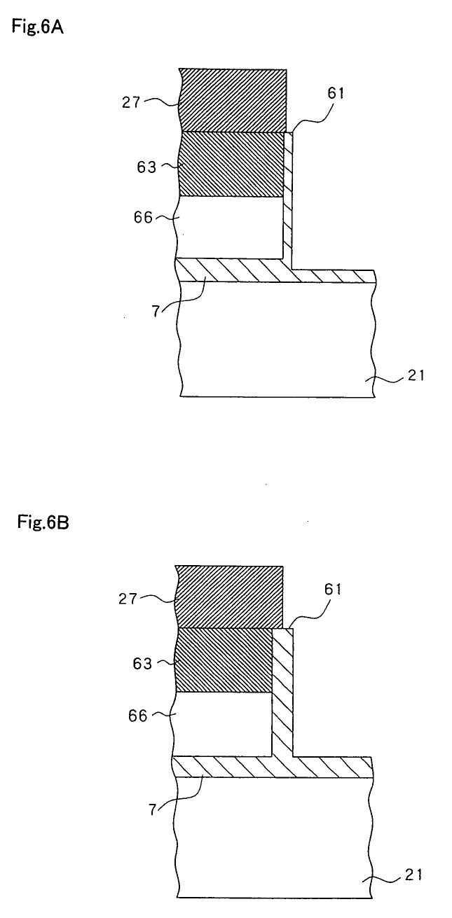

FIGS. 6A and 6B are fragmentary cross-sectional views of a gate electrode, showing the manner in which the treatment condition shown in FIG. 5 is applied to the side oxidization of the gate electrode. In FIGS. 6A and 6B, the gate electrode has been formed in the same manner as described above with respect to the related art. Specifically, the gate electrode is formed by depositing phosphorus-doped polycrystalline silicon film 66, tungsten silicide film 63, and protective film 27 on gate oxide film 7, and thereafter patterning the films to a predetermined configuration by lithography and etching. Gate oxide film 7 is formed on silicon substrate 21.

As shown in FIG. 6A, silicon oxide film 61 is formed to a thickness ranging from 1 to 3 nm on a side wall of the gate electrode at a temperature of 1000° C. in the initial oxidization phase. Then, as shown in FIG. 6B, the thickness of silicon oxide film 61 on the side wall of the gate electrode is increased at a temperature of 1100° C. in the additional oxidization phase. As shown in FIGS. 6A and 6B, the region of gate oxide film 7 on which the gate electrode is not disposed also has its thickness increased. In the initial oxidization phase at the lower temperature, a tungsten contamination from tungsten suicide film 63 is reduced. In the additional oxidization phase at the higher temperature, the layer resistance of tungsten silicide film 63 is reduced.

Temperature conditions for the initial oxidization phase will be described in detail below. In the initial oxidization phase, as shown in FIG. 4, at 1000° C., the tungsten contamination is reduced to ¼ of the tungsten contamination at 1050° C., and, at 950° C., the tungsten contamination is reduced to 1/15 of the tungsten contamination at 1050° C. If the assembly is oxidized at a lower temperature, then the tungsten contamination might be further lowered, but the oxidizing rate would be reduced, resulting in a longer oxidization time. Therefore, there is a limitation on efforts to lower the temperature. Consequently, the initial oxidization phase should be performed at a temperature of 1000° C. or lower for effectively reducing the tungsten contamination, and should preferably be performed at a temperature of 950° C. or higher for maintaining a desired oxidizing rate.

A lower limit for the oxidized amount of material in the initial oxidization phase will be described below. The amount of material oxidized in the initial oxidization phase needs to be in the range from 1 to 3 nm in terms of film thickness so that the contamination due to diffused tungsten in the subsequent high-temperature additional oxidization phase may be small. With respect to the lower limit for the oxidized amount of material in the initial oxidization phase, a film thickness of about 1 nm or greater is capable of preventing the silicon substrate from being oxidized as the diffusion of tungsten into the silicon oxide film is relatively slow. As shown in FIG. 6A, silicon oxide film 61 is also formed on a side wall of tungsten silicide film 63 in the initial oxidization phase. Therefore, if the oxidized amount of material in the initial oxidization phase is about 1 nm or greater in terms of film thickness, then tungsten will not be scattered from the side wall in the subsequent additional oxidization phase.

An upper limit for the oxidized amount of material in the initial oxidization phase will be described below. Since oxidization goes on below the gate electrode if the oxidized amount of material grows in the initial oxidization phase, it is necessary to set an upper limit for the oxidized amount of material in order to prevent oxidization from progressing below the gate electrode. If the assembly is oxidized at a temperature lower than 1050° C., then the difference between the oxidized rates of phosphorus-doped poly crystalline silicon film 66 and the semiconductor substrate below gate oxide film 66 which is exposed after the gate electrode is processed, increases, and the oxidized amount of phosphorus-doped polycrystalline silicon film 66 becomes relatively greater. Therefore, the oxidized amount of the lower portion of the gate electrode below phosphorus-doped polycrystalline silicon film 66 is increased. If the oxidized amount of the lower portion of the gate electrode becomes too large, gate oxide film 7 at an end of the lower portion of the gate electrode becomes effectively thick. As a result, the threshold voltage of the transistor rises. If the film thickness of the gate oxide film below the gate electrode varies, then the threshold voltage of the transistor tends to vary greatly. The oxidized amount of material which will not give rise to the above problem should preferably be 3 nm or smaller in terms of film thickness in the initial oxidization phase.

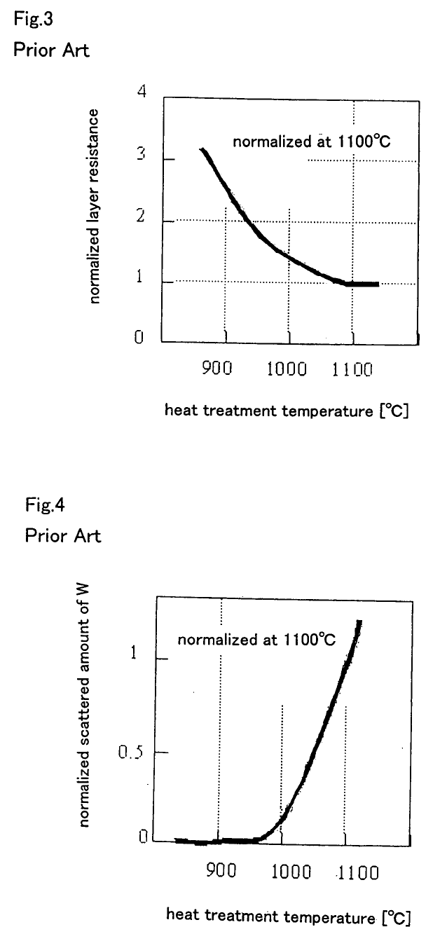

Temperature conditions for the additional oxidization phase will be described in detail below. The temperature in the additional oxidization phase needs to be 1050° C. or higher for sufficiently lowering the layer resistance of tungsten silicide film 63, as shown in FIG. 3. However, the reduction in the layer resistance of tungsten silicide film 63 becomes saturated at a temperature of 1150° C. or higher. Therefore, the temperature in the additional oxidization phase should preferably be in a range from 1050° C. to 1150° C.

The oxidized amount of material in the additional oxidization phase will be described below. As shown in FIG. 6B, in the additional high-temperature oxidization phase, the assembly is oxidized to a desired film thickness from the standpoint of the withstand voltage of the gate oxide film. Since the oxidized amount of material determines the performance of the semiconductor device, it is selected depending on the type of the semiconductor device. For cell transistors for use in DRAMs, the film thickness should preferably be as large as at least 5 nm. For MOS transistors which need to have a current drive capability, the film thickness should preferably be smaller, but needs to be at least 3 nm.

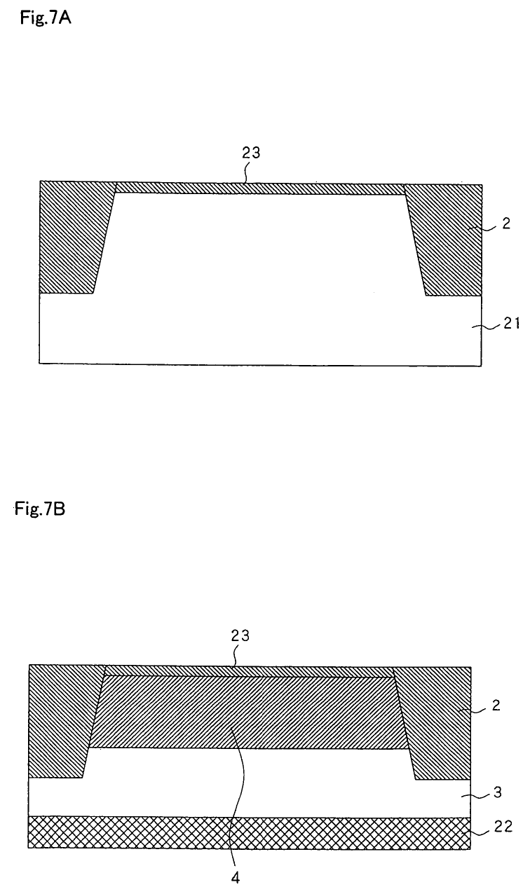

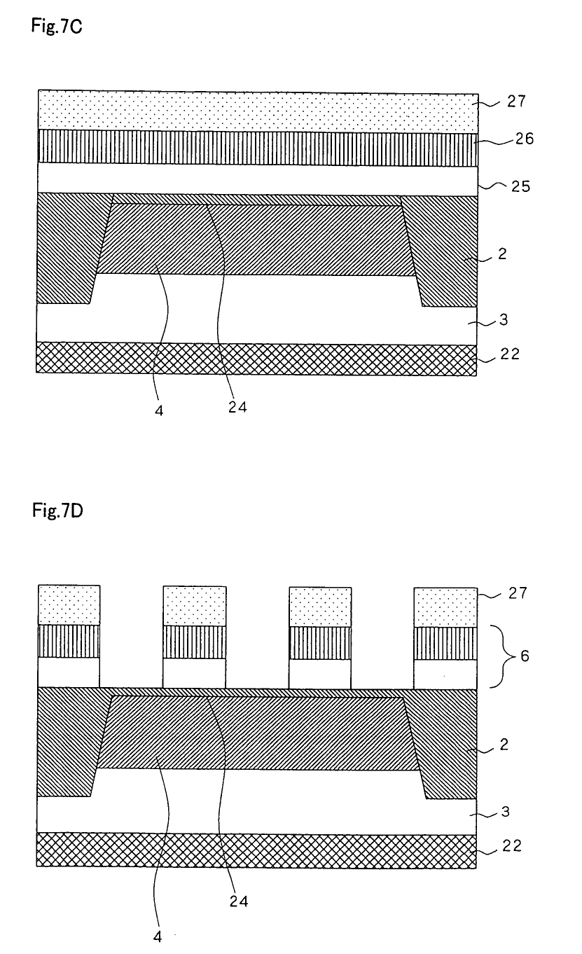

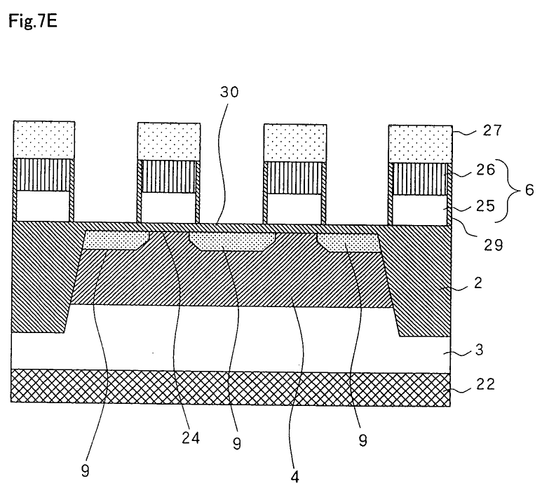

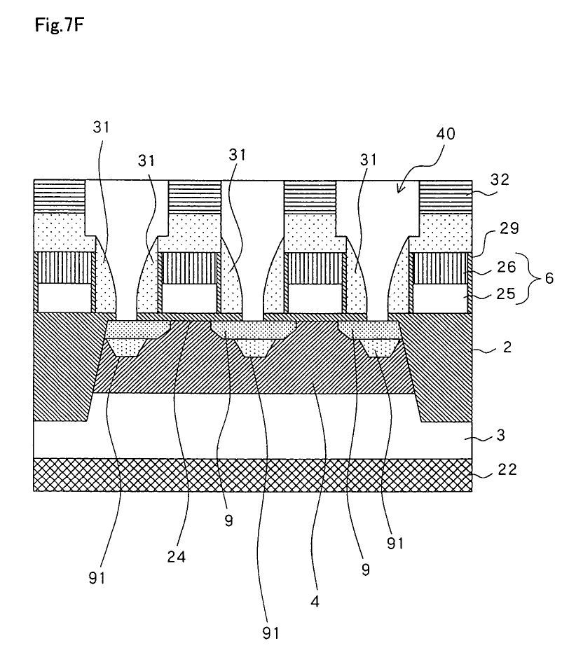

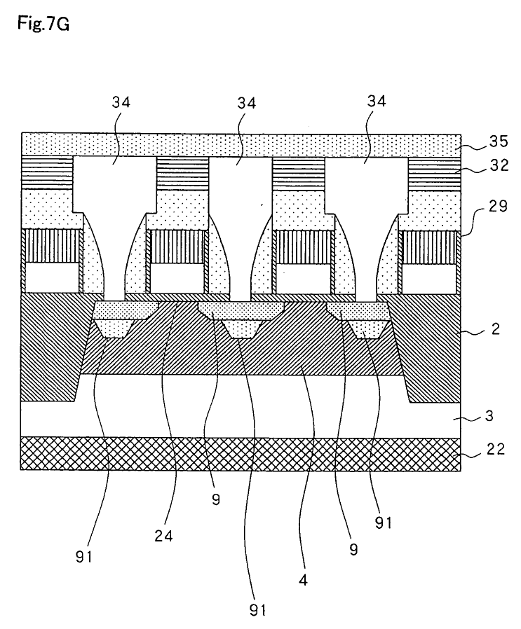

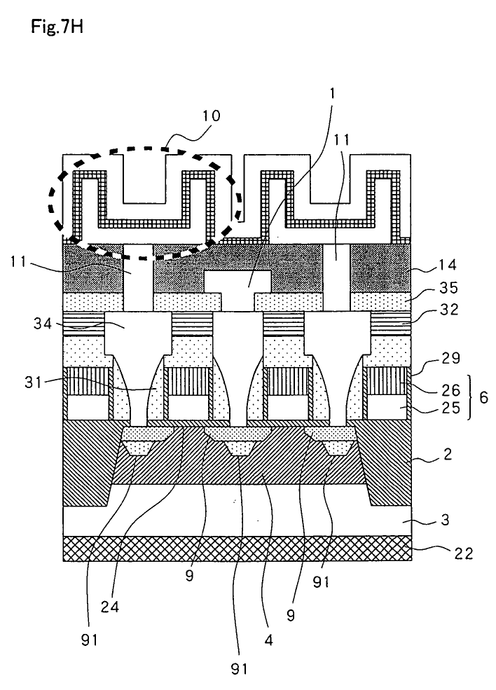

A process of fabricating a cell transistor for use in a DRAM according to an embodiment of the present invention will be described below. FIGS. 7A through 7H are cross-sectional views illustrative of a process of manufacturing a DRAM cell. Processing details that are identical to those described above with respect to the related art will not be described below.

As shown in FIG. 7A, silicon oxide film 23 is deposited to a thickness of 10 nm on the surface of silicon substrate 21, and a groove-like device isolating region where insulating layer 2 is buried in the principal surface of silicon substrate 21 is formed, in the same manner as with the conventional process. Thereafter, phosphorus ions are implanted to form n-type buried well layer 22 and boron ions are implanted to form p-type well layer 3, in the same manner as with the conventional process. After the boron ions are implanted, the assembly is heated at 1000° C. for 30 minutes. Thereafter, boron ions are implanted at 10 keV with 9E12/cm² to form p-type channel doped layer 4, after which the assembly is heated at 1000° C. for 10 seconds in a nitrogen atmosphere (see FIG. 7B).

After silicon oxide film 23 is removed, gate oxide film 24 having a thickness of 7 nm is formed by thermal oxidization. Phosphorus-doped polycrystalline silicon film 25 having a thickness of 70 nm and tungsten silicide film 26 having a thickness of 100 nm are formed on gate oxide film 24. Then, a laminated film structure including a silicon oxide film having a thickness of 30 nm and a silicon nitride film having a thickness of 150 nm are formed as protective film 27 on tungsten silicide film 26 (see FIG. 7C).

A resist having a predetermined pattern is formed by lithography on protective film 27. Thereafter, the assembly is subjected to anisotropic dry etching from above the resist, thereby removing protective film 27, tungsten silicide film 26, and phosphorus-doped polycrystalline silicon film 25 in areas not covered with the resist. Then, the resist is removed. As shown in FIG. 7D, gate electrodes 6 is now formed.

Then, as shown in FIG. 7E, silicon oxide films 29 are formed by thermal oxidization on side walls of phosphorus-doped polycrystalline silicon film 25 and tungsten silicide film 26 of gate electrodes 6. Specifically, oxide films having a thickness of 1.5 nm are formed on the side walls of gate electrodes 6 at a temperature of 1000° C. in the initial oxidization phase, and the oxide films are grown to a total thickness of 10 nm at a temperature of 1100° C. in the additional oxidization phase. The above oxidization is performed on the remaining portion of gate oxide film 24 that is exposed after gate electrodes 6 are formed, thereby forming silicon oxide film 30 having a thickness of 8 nm on the surface of the silicon substrate.

After silicon oxide films 29 are formed on the side walls of gate electrodes 6, phosphorus ions are implanted at 15 keV with 9E12/cm² and at 10 keV with 9E12/cm² to form n-type low-concentration diffused layers 9 which will serve as source and drain electrodes. Subsequently, the assembly is heated at 1000° C. for 10 seconds in a nitrogen atmosphere (see FIG. 7E). The formation of diffusion layers of peripheral transistors will not be described in detail below as it is the same as with the conventional process.

Then, after silicon nitride film 31 having a thickness of 50 nm and silicon oxide film 32 having a thickness of 300 nm are formed, the surface of silicon oxide film 32 is planarized by etching back and CMP (Chemical and Mechanical Polishing), for example. Then, a resist having a predetermined opening pattern is formed on silicon oxide film 32 by lithography in order to form openings to be filled by plugs. Thereafter, the assembly is subjected to anisotropic dry etching from above the resist, thereby forming plug openings 40 extending from silicon oxide film 32 to n-type low-concentration diffused layers 9, after which the resist is removed (see FIG. 7F).

Then, phosphorus ions are implanted for electric field relaxation and arsenic ions are implanted for reducing the diffused layer resistance. The phosphorus ions are implanted at 30 keV with 1E13/cm², and the arsenic ions are implanted at 20 keV with 2E13/cm². Between the implantation of the phosphorus ions and the implantation of the arsenic ions, the assembly is heated at 950° C. for 10 seconds in a nitrogen atmosphere. As shown in FIG. 7F, phosphorus-doped layers 91 are formed for electric field relaxation.

Then, after a phosphorus-doped polycrystalline silicon film having a thickness of 100 nm is formed, the phosphorus-doped polycrystalline silicon film is removed by etching back until silicon oxide film 32 is exposed. Now, as shown in FIG. 7G, plugs 34 of the phosphorus-doped polycrystalline silicon film are formed in plug openings 40. Then, silicon oxide film 35 having a thickness of 100 nm is deposited on the surface formed so far of the assembly, after which the assembly is heated at 900° C. for 10 seconds.

Thereafter, bit line 1 is formed in the same manner as with the conventional process, and then interlayer insulating film 14 is formed. After plugs 11 are formed, capacitors 10 are formed, thereby producing a DRAM cell as shown in FIG. 7H.

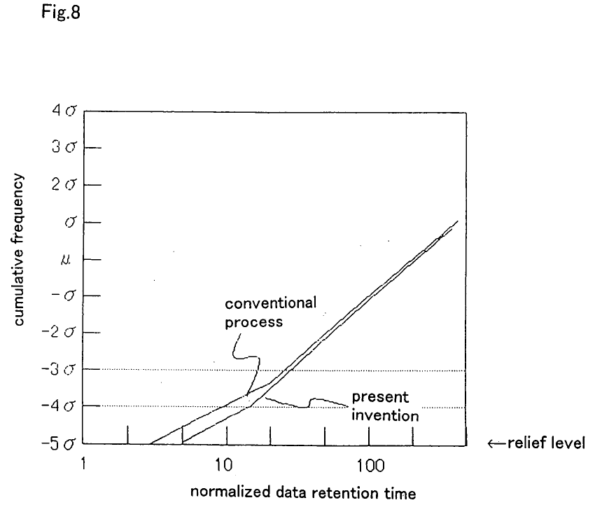

Data retention characteristics of the DRAM fabricated by the method according to the present invention will be described in comparison with those of a DRAM fabricated by the conventional process will be described below. FIG. 8 is a graph showing data retention characteristics of the DRAM. In FIG. 8, the vertical axis represents the cumulative frequency and the horizontal axis the normalized data retention time.

As shown in FIG. 8, a comparison between the normalized data retention times at the cumulative frequency of a relief level (−5 sigma) according to the inventive method and the conventional process shows that the normalized data retention time according to the inventive method is twice the normalized data retention time according to the conventional process, indicating that the data retention characteristics of the DRAM fabricated by the method according to the present invention are improved about twice. Furthermore, since the word line resistance is of a sufficiently low value, a reduction caused in the performance owing to the word line resistance is prevented from occurring.

As described above, the principles of the present invention as they are applied to a cell transistor for a DRAM are capable of improving the data retention characteristics of the DRAM. Moreover, the layer resistance of the tungsten silicide films of the gate electrodes is reduced thereby to increase the operating speed of the transistor, allowing the DRAM to operate more quickly.

As the data retention characteristics of the DRAM are improved, the refresh cycle is extended to reduce electric power that is consumed by charging and discharging data. Furthermore, since the power consumption is reduced, the present invention is applicable to the fabrication of semiconductor devices for use in cellular phones and semiconductor devices for use in apparatus that operate at high temperatures.

The refractory metal for use as the material of the gate electrodes is not limited to tungsten, but may be titanium, tantalum, molybdenum, or the like.

While a preferred embodiment of the present invention has been described using specific terms, such description is for illustrative purposes only, and it is to be understood that changes and variations may be made without departing from the spirit or scope of the following claims.

What is claimed is:

1. A method of manufacturing a semiconductor device having a gate electrode made of a material containing a refractory metal, comprising the steps of:
forming said gate electrode and then oxidizing said gate electrode to form an oxide film for covering an exposed side surface of the gate electrode, at a predetermined temperature in an initial oxidization phase; and
thereafter, oxidizing said gate electrode at a temperature higher than said predetermined temperature in an additional oxidization phase.

2. A method according to claim 1, wherein said predetermined temperature in said initial oxidization phase ranges from 950° C. to 1000° C.

3. A method according to claim 1, wherein said temperature in said additional oxidization phase ranges from 1050° C. to 1150° C.

4. A method according to claim 1, wherein said oxide film formed in said initial oxidization phase has a thickness ranging from 1 to 3 nm.
